(19) United States
(12) Patent Application Publication
(10) Pub. No.: US 2007/0257728 A1
(43) Pub. Date: Nov. 8, 2007

(54) Microelectromechanical multi-stage oscillator

(75) Inventors: Bernhard E. Boser, Berkeley, CA (US); Crist Y. Lu, Fremont, CA (US); Aaron Partridge, Santa Clara, CA (US)

Correspondence Address: PATTERSON & SHERIDAN, L.L.P., 3040 POST OAK BOULEVARD, SUITE 1500, HOUSTON, TX, 77056, US

(73) Assignee: SiTime Corporation

(21) Appl. No.: 11/417,951

(22) Filed: May 3, 2006

(51) Int. Cl. H03K 3/38

(52) U.S. Cl. 327/528

(57) ABSTRACT

Embodiments of an oscillator circuit are described. Embodiments described herein include an oscillator circuit suitable for a resonator with relatively high motional impedance, thus requiring relatively high amplification and having relatively high sensitivity to noise. However, the embodiments described are not intended to be limited to use with any particular type of resonator. In one embodiment, alternating current (AC) coupling, or capacitive coupling, is used in part to decouple the bias voltage placed on the resonator from the operating point of the amplifier, allowing one voltage to be high relative to the other. In an embodiment, some legs, or all legs of the circuit that includes drive circuitry and a resonator include differential signaling.

### TECHNICAL FIELD

The invention is in the field of oscillator circuits to generate timing reference signals from resonator devices, and particularly microelectromechanical (MEMS) resonator devices.

### BACKGROUND

Most electronic products, for example computers, cell-phones, cameras, CD players, and watches, require at least one highly accurate and stable timing reference to synchronize the circuitry. Timing references typically include a resonator that resonates at a characteristic frequency. Examples of resonators include quartz crystal resonators, surface acoustic wave (SAW) resonators, ceramic resonators, microelectromechanical resonators, etc. In order to obtain a usable timing reference signal from a resonator, many circuits have been designed to drive the resonator and produce an output signal. These circuits are variously referred to as oscillator circuits, drive circuits, resonator drivers, etc.

Oscillator circuits are generally designed for or optimized for the particular type of resonator to which they are connected. Oscillator circuits designed and used for quartz crystal or SAW or ceramic resonators are not generally suitable for microelectromechanical resonators. For example, microelectromechanical resonators are small relative to other types of resonators and often have high motional resistance and low power handling limits. The oscillator circuits used for these resonators must take these characteristics into consideration, for example with high gain, drive power control, and low electrical noise.

All of the above requirements should be met by an oscillator circuit that should be built with common circuit fabrication technologies, like CMOS, that should not be overly complex, and should operate is common application environments.

### BRIEF DESCRIPTION OF THE DRAWINGS

FIG. 1 is a block diagram of a timing reference signal generating system according to an embodiment.

FIG. 2 is a block diagram of a package including the timing reference signal generating system of FIG. 1 on a single integrated circuit chip.

FIG. 3 is a block diagram of a package including the timing reference signal generating system of FIG. 1 on two chips.

FIG. 4 is a circuit diagram of elements of a timing reference signal generating system according to an embodiment.

FIG. 5 is a circuit diagram of elements of a timing reference signal generating system according to another embodiment.

FIG. 6 is a circuit diagram of elements of a timing reference signal generating system according to another embodiment.

FIG. 7 is a circuit diagram of elements of a timing reference signal generating system according to another embodiment.

FIG. 8 is a circuit diagram of elements of a timing reference signal generating system according to another embodiment.

FIG. 9 is a circuit diagram of elements of a timing reference signal generating system according to another embodiment.

FIG. 10 is a circuit diagram of elements of a timing reference signal generating system according to another embodiment.

FIG. 11 is a circuit diagram of an amplifier circuit according to an embodiment.

FIG. 12A is a transistor level circuit diagram of a front stage of an amplifier according to an embodiment.

FIG. 12B is a transistor level circuit diagram of a gain stage of an amplifier according to an embodiment.

FIG. 12C is a transistor level circuit diagram of a limit stage of an amplifier according to an embodiment.

FIG. 12D is a transistor level circuit diagram of a level translator according to an embodiment.

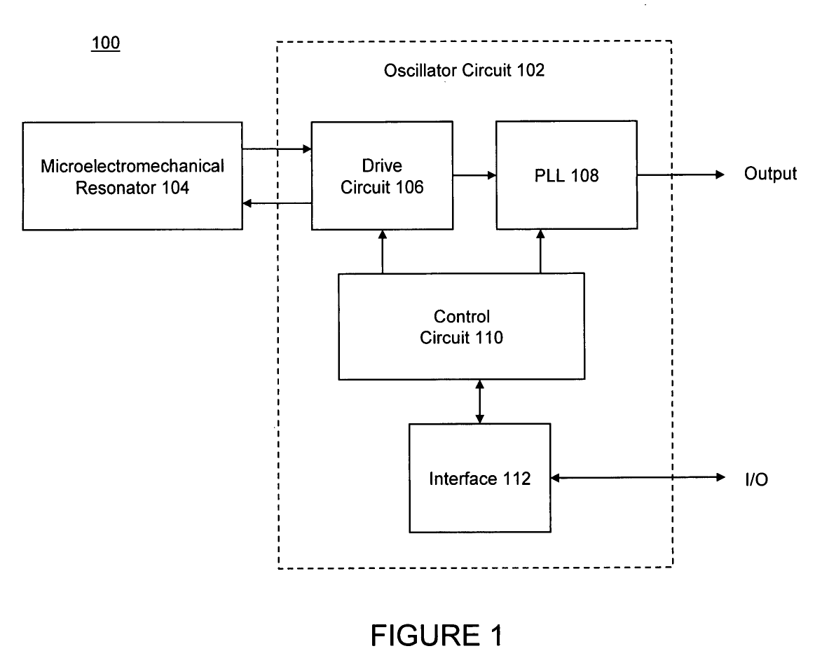

In the drawings, the same reference numbers identify identical or substantially similar elements or acts. To easily identify the discussion of any particular element or act, the most significant digit or digits in a reference number refer to the Figure number in which that element is first introduced (e.g., element 102 is first introduced and discussed with respect to FIG. 1). The drawings illustrate particular embodiments for the purpose of describing the claimed invention, and are not intended to be exclusive or limiting in any way.

### DETAILED DESCRIPTION

Embodiments described herein include an oscillator circuit suitable for a resonator with relatively high motional impedance, thus requiring relatively high amplification and having relatively high sensitivity to noise. However, the embodiments described are not intended to be limited to use with any particular type of resonator. In one embodiment, alternating current (AC) coupling, or capacitive coupling, is used in part to decouple the bias voltage placed on the resonator from the operating point of the amplifier, allowing one voltage to be high relative to the other. In an embodiment, some legs, or all legs of the circuit that includes drive circuitry and a resonator include differential signaling. Differential signaling is helpful in minimizing noise in the circuit and in managing stray capacitances. In an embodiment, the amplifier is a multi-stage amplifier including a gain control stage that is programmable to limit the amplifier output, which sets power requirements for the specific resonator. In an embodiment, the gain control stage is programmable by selecting a level at which to clamp or clip the amplifier output, but the invention is not so limited.

FIG. 1 is a block diagram of a timing reference signal generating system 100 according to an embodiment. The system 100 includes a microelectromechanical resonator 104 and drive circuit 102. In various other embodiments, other types of resonators can be used. The oscillator circuit 102 includes drive circuit 106 coupled to a phase locked loop (PLL) 108. The drive circuit 106 is described in more detail below. The drive circuit 106 outputs a signal with a frequency determined by the microelectromechanical resonator to the PLL 108. The PLL outputs a timing reference signal. In some cases the PLL may be omitted, in which case, for example, the drive circuit 106 provides the output reference signal. In some cases other circuits may be used in place of the PLL 108, for instance a delay lock loop (DLL), a direct digital synthesizer (DDS), or various other frequency generators or synthesizers. Any other circuit, whether now known or later developed, may be inserted in place of 108 and is still intended to fall within the scope of the embodiments disclosed and claimed.

A control circuit 110 is coupled to the drive circuit 106 and the PLL 108. It may be connected to only the drive circuit 106 or only to the PLL 108. The control circuit 110 may be any one of a variety of known controllers, including a state machine, a microprocessor, or any of a wide variety of circuits that can supply a control output. The control circuit may include memory devices, including but not limited to, read only memory (ROM), random access memory (RAM), reprogrammable PROM, electrically erasable programmable ROM (EEPROM), one-time programmable ROM (OTPROM), fuse or antifuse OTPROM, etc. The control circuitry 110, in an embodiment, manages and may store configuration information for the oscillator. For example, configuration information may include data to determine an amount to limit an output of an amplifier signal in the drive circuit 106, as described more fully below. The configuration information may also include data to program the oscillator circuit 102 to output one or more specific frequencies within the range of frequencies derivable from the resonator 104, but the embodiment is not so limited.

An interface 112 may be coupled to the control circuit 110 for inputting information, including for instance configuration information as described above, and for outputting information, including for instance status information. In an embodiment, the interface 112 is a serial interface, but the embodiment is not so limited. In some cases the interface may be omitted.

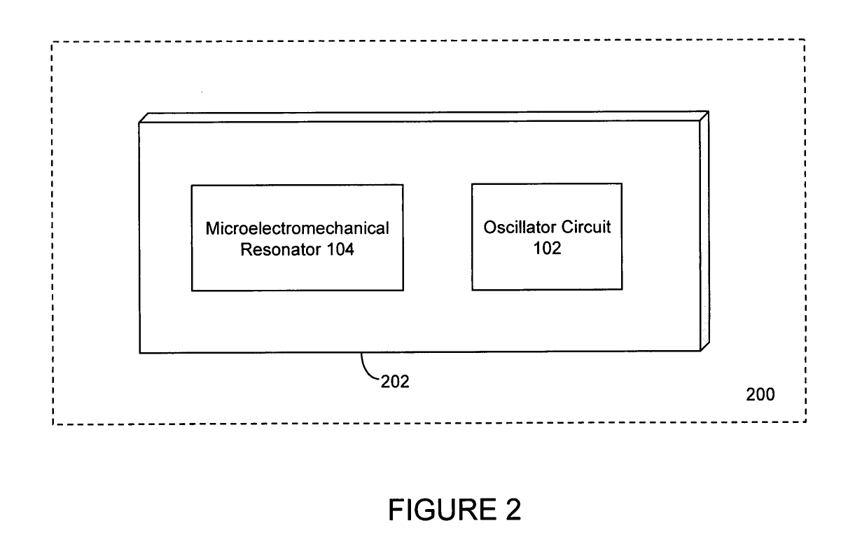

FIG. 2 is a block diagram of a package 200 including the timing reference signal generating system of FIG. 1 on a single integrated circuit chip 202. The single integrated circuit chip 202 includes both the microelectromechanical resonator 104 and the oscillator circuit 102. In an embodiment, the package 200 is a known four-pin package, as commonly used for quartz crystal oscillators, but the embodiment is not so limited.

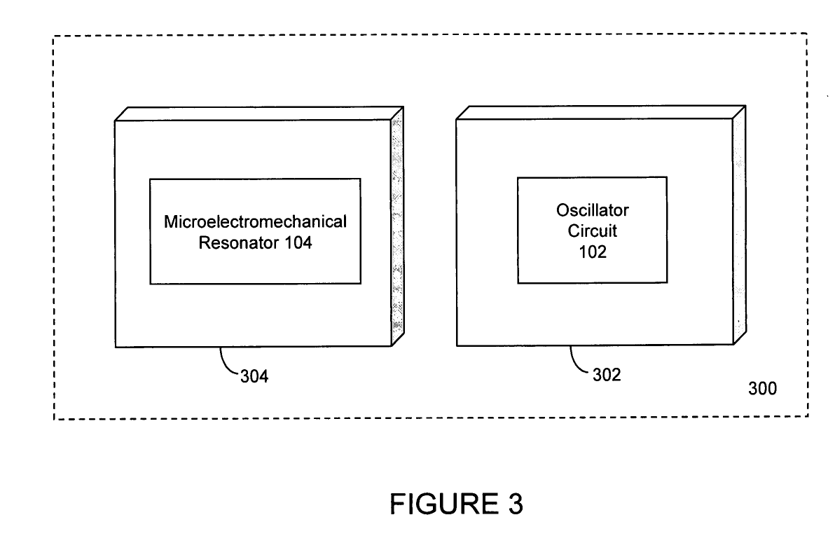

FIG. 3 is a block diagram of a package 300 including the timing reference signal generating system of FIG. 1 on two integrated circuit chips 302 and 304. The oscillator circuit 102 is on the integrated circuit chip 302, and the microelectromechanical resonator 104 is on the chip 304. In an embodiment, the package 200 is a known four-pin package, as commonly used for quartz crystal oscillators, but the embodiment is not so limited.

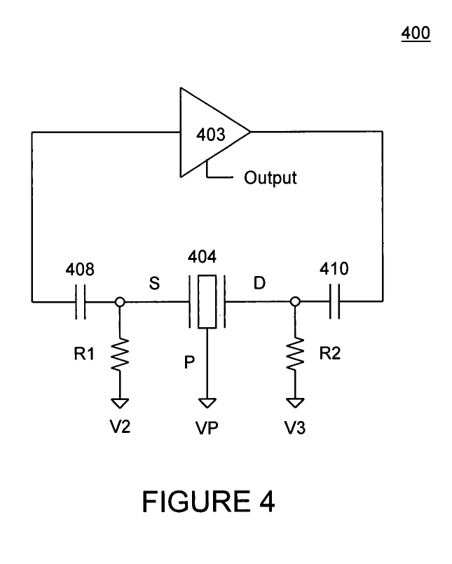

FIG. 4 is a circuit diagram of elements of a timing reference signal generating system 400 according to an embodiment. The elements of the system 400 include a resonator 404 and components of drive circuitry, including an amplifier 403. The amplifier 403 drives the resonator 404 and provides a signal on the amplifier output that is provided, for example, to a PLL. The resonator 404 is alternating current (AC) coupled, alternately described as capacitively coupled, such that the bias voltage on the sense node of the resonator 404 is decoupled from the operating point voltage on the input of the amplifier 403, and the bias voltage on the drive node of the resonator 404 is decoupled from the operating point voltage on the output of the amplifier 403. The direct voltage (DC) biases on the resonator and amplifier are blocked by the capacitors such that the amplifier and resonator can have different DC voltages while the AC signals are conducted across the capacitors.

The resonator 404 includes a sense node “S”, a drive node “D”, and a polarizing node “P”. Node S is connected to one side of capacitor 408 and to a resistor R1. The other side of the capacitor 408 is connected to the input of the amplifier 403. A bias voltage V2 on the resistor R1 biases the voltage at node S. Node D is connected to one side of a capacitor 410 and to a resistor R2. The other side of the capacitor 410 is connected to the driving output of the amplifier 403. A bias voltage V3 on the resistor R2 biases the voltage at node D. A bias voltage, or polarizing voltage VP is placed on node P. The resistors may be implemented in conductive materials or may be transistors configured to functions as resistors, or may have many other embodiments, for example back-to-back diodes. The embodiment is not meant to be limited by this example.

In one embodiment, node S and node D are each maintained at zero volts, common, or ground. The bias across the resonator in this arrangement is then the voltage VP applied to the resonator.

One advantage of this capacitively coupled bias is that microelectromechanical resonators often benefit from the maximized bias voltages allowed by this arrangement. The bias voltage across the resonator, namely VP minus V2 and VP minus V3 can be larger given a particular VP than it would be if the resonator input and output were directly coupled to the amplifier.

A second advantage of this arrangement is that microelectromechanical resonators can change frequency slightly as a function of bias voltage and the capacitive coupling provides the advantage of separating the amplifier's operating point voltage from the resonator's net bias. Since the amplifier's operating point can vary with temperature, from device to device, and over time; this arrangement can lead to increased accuracy of the microelectromechanical oscillator. This gives finer control over the frequency of the resonator by controlling net bias, for example in the presence of temperature fluctuations, than would be the case if the resonator 404 were directly coupled to the amplifier 403.

A third advantage of this arrangement is its suitability for applications that require a low net bias voltage on the resonator 404. In these cases the desired bias may be less than the operating point of the amplifier 403, which is possible with capacitive coupling.

A fourth advantage of this arrangement is its suitability for applications that require a relatively high bias but have a low supply voltage (for example 1.8V, 2.5V or 3.3V), as is common for integrated circuits. The bias voltage VP in this embodiment can be generated on chip using a voltage multiplier. As VP increases, the difficulty involved with generating VP increases non-linearly. If the resonator 404 were directly coupled to the amplifier 403, the operating point voltage required by the amplifier would be added to VP to for application to node P. Because the difficulty in generating VP increases non-linearly with voltage, this added voltage is undesirable, but is avoided with capacitive coupling.

In another embodiment, VP is zero to maintain node P at zero, while node S and node D are biased by non-zero voltages V2 and V3, respectively. In an embodiment, V2 is equal to V3, but the embodiment is not so limited and V2 and V3 may differ. The advantages discussed above are still gained by this embodiment in which V2 and V3 are non-zero or not equal.

It is contemplated that a capacitive coupling may be used on only one of the positions, for examples in the drive but not the sense, or in the sense but not the drive. This would be advantageous for some forms of amplifier circuit 403.

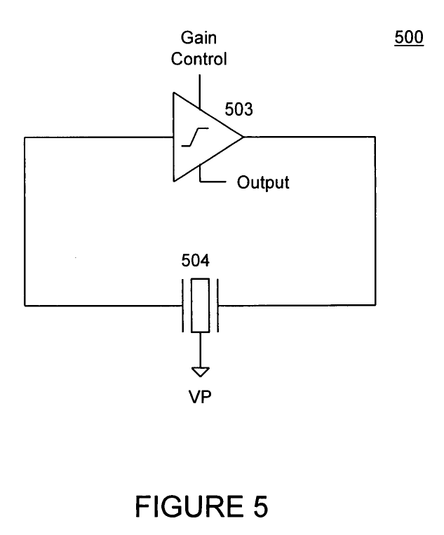

FIG. 5 is a circuit diagram of elements of a timing reference signal generating system 500 according to another embodiment. The elements of the system 500 include a resonator 504 and components of a drive circuit, including an amplifier 503. The amplifier 503 includes gain control circuitry to limit the output of the amplifier 503. In an embodiment, the output signal is clamped, or clipped so that a sine wave output, if clipped, looks like a square wave. In an embodiment, the amount of clipping (meaning the level at which an output waveform is clipped) is programmable or selectable by a control circuit 110 (FIG. 1). The amount of clipping is directly related to the amount of amplitude power with which the resonator 504 is driven. A selectable clipping level is useful because there is typically some variation (due to processing, etc.) between resonators that cause different resonators to operate at different optimum power input levels. A selectable clipping level is also useful to compensate for changes in the resonator, particularly resonant Q, over temperature, in which case the control circuit may change the clipping level dynamically as a function of measured temperature.

Providing the limiting function in an amplifier can be a relatively simple and economical solution as compared to alternative approaches, including gain control circuitry external to the amplifier 503, for example.

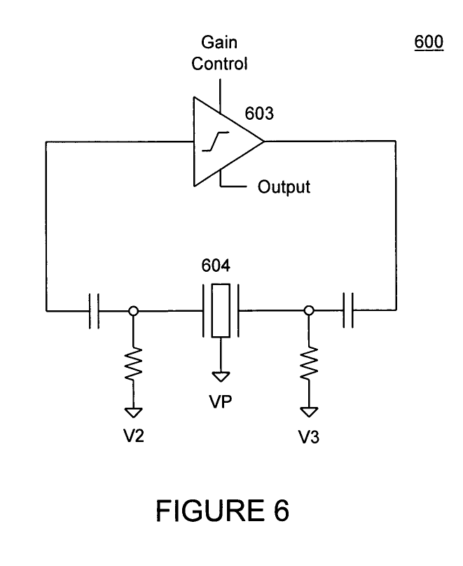

FIG. 6 is a circuit diagram of elements of a timing reference signal generating system 600 according to another embodiment. The elements of the system 600 include a resonator 604 and components of drive circuitry, including the amplifier 603 with gain control as described with reference to FIG. 5. The amplifier 603 drives the resonator 604 to provide a signal on its output that is coupled, for example, to a PLL or other circuitry. The resonator 604 is capacitively coupled, such that a voltage on a sense or drive node of the resonator 604 is decoupled from a voltage on the input or output of the amplifier 603.

This embodiment can have the biasing advantages described above for circuit 400 in FIG. 4 and the drive control advantages described for circuit 500 in FIG. 5. For the sake of brevity the advantages will not be reiterated here, but are understood to apply. In addition, the effect of resonator bias and drive amplitude are interrelated and there can be benefit to controlling them simultaneously or for controlling one while the other is fixed. The combination of bias freedom provided by capacitive coupling and drive amplitude control provided by clipping can be synergistic.

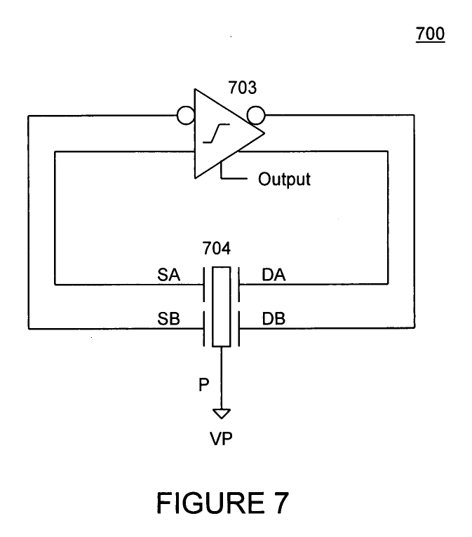

FIG. 7 is a circuit diagram of elements of a timing reference signal generating system 700 according to another embodiment. The elements of the system 700 include a resonator 704 and components of drive circuitry, including an amplifier 703. The resonator 704 is differentially coupled to the amplifier 704. The resonator 704 includes drive node DA, drive node DB, sense node SA, sense node SB, and polarizing node P.

Differential coupling provides the advantage of minimizing the susceptibility of the sense signals to common mode noise. This reduction can be, for example, on the order of 30 dB or more. This is especially significant in applications employing a resonator that generates a small signal, such as a microelectromechanical resonator.

Differential coupling also reduces the affect of parasitic capacitance. In many applications, stray capacitances (not shown) across the resonator, for example from node(s) D to node(s) S can be significant. In single-ended (non-differential) arrangements, this capacitance can become a limiting factor for the drive circuitry. In a differential arrangement, however, the capacitances from DA to SA, from DB to SB, from DA to SB, and from DB to SA, can compensate one another. To the extent that the capacitors are matched, the signals through them can produce zero net differential signal and the effect of the capacitors can be canceled.

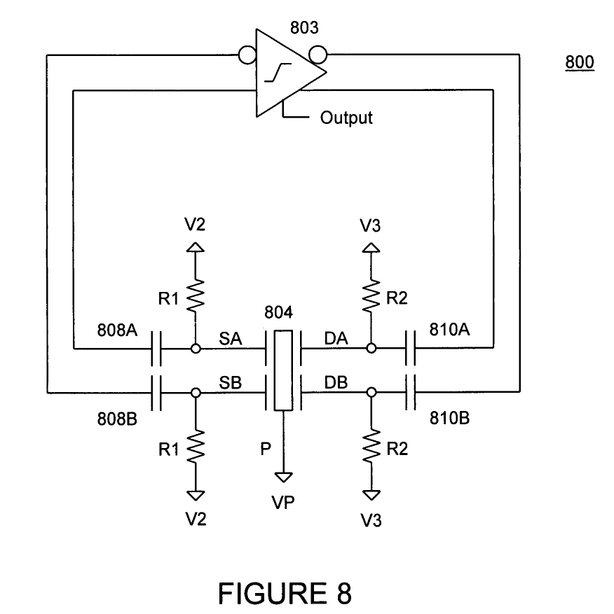

FIG. 8 is a circuit diagram of elements of a timing reference signal generating system 800 according to another embodiment. The elements of the system 800 include a resonator 804 and components of drive circuitry, including an amplifier 803. The system 800 includes differential signaling and capacitive coupling. The resonator 804 is differentially coupled to the amplifier 803. The resonator 804 includes a sense node SA, a drive node DA, a sense node SB, a drive node DB, and a polarizing node P. Node SA is connected to one side of a capacitor 808A, and to a resistor R1. The other side of the capacitor 808A is connected to the input of the amplifier 803. Node SB is connected to one side of a capacitor 808B, and to a resistor R1. The other side of the capacitor 808B is connected to the input of the amplifier 803. Node DA is connected to one side of a capacitor 810A, and to a resistor R2. The other side of the capacitor 810A is connected to the driving output of the amplifier 803. Node DB is connected to one side of a capacitor 810B, and to a resistor R2. The other side of the capacitor 810B is connected to the driving output of the amplifier 803.

Voltages V2 and V3 are applied to maintain a bias voltage at nodes SA and SB, and DA and DB, respectively. A polarizing voltage, VP, is applied to node P to maintain node P at a bias voltage. In one embodiment, V2 and V3 are zero volts, while VP is a non-zero voltage. In other embodiments, V2 and V3 are non-zero voltages, while VP is zero volts. In an embodiment, V2 and V3 are the same non-zero voltage, but embodiments are not so limited, and V2 and V3 may be different voltages, indeed VP, V2, and V3 may all be non zero and may all be different. The advantages of differential signaling and the advantages of capacitive coupling as described above are also realized in the embodiments of FIG. 8.

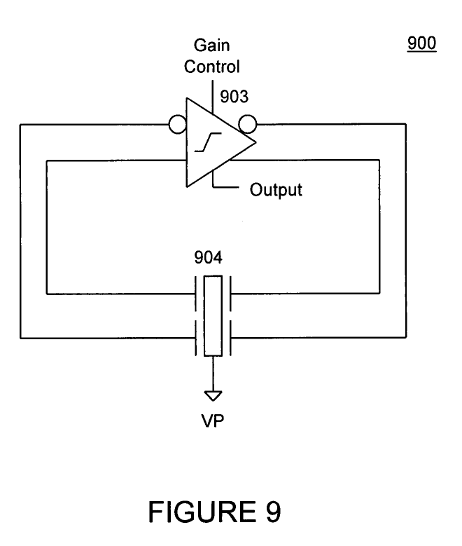

FIG. 9 is a circuit diagram of elements of a timing reference signal generating system 900 according to another embodiment. The elements of the system 900 include a resonator 904 and components of drive circuitry, including an amplifier 903. The system 900 includes differential signaling and gain control capability in the amplifier 903. In an embodiment, the amplifier 903 is a limiting amplifier that programmably clips its output signal as described with reference to the amplifier 503 of FIG. 5. In an embodiment, the amount of clipping (meaning the level at which an output waveform is clipped) is programmable or selectable by a control circuit such as circuit 110 (FIG. 1). The advantages of economically and selectably clipping the output signal of the amplifier as described with reference to FIG. 5 are also realized in the embodiment of FIG. 9. In addition, all of the advantages of differential signaling as previously described are also realized in the embodiment of FIG. 9.

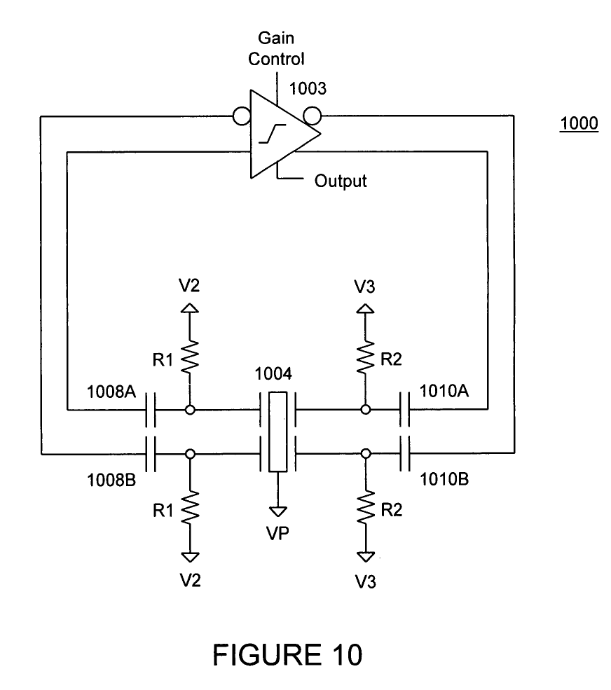

FIG. 10 is a circuit diagram of elements of a timing reference signal generating system 1000 according to another embodiment. The elements of the system 1000 include a resonator 1004 and components of drive circuitry, including an amplifier 1003. The system 1000 includes differential signaling, capacitive coupling, and gain control in the amplifier 1003. Capacitors 1008, resonator 1004, capacitors 1010, and resistors R1 and R2 are coupled and function as described with reference with FIG. 8. The amplifier 1003 is a limiting amplifier as described with reference to FIG. 5, but embodiments are not so limited. All of the previously described advantages of the described features are also realized in the embodiment of FIG. 10.

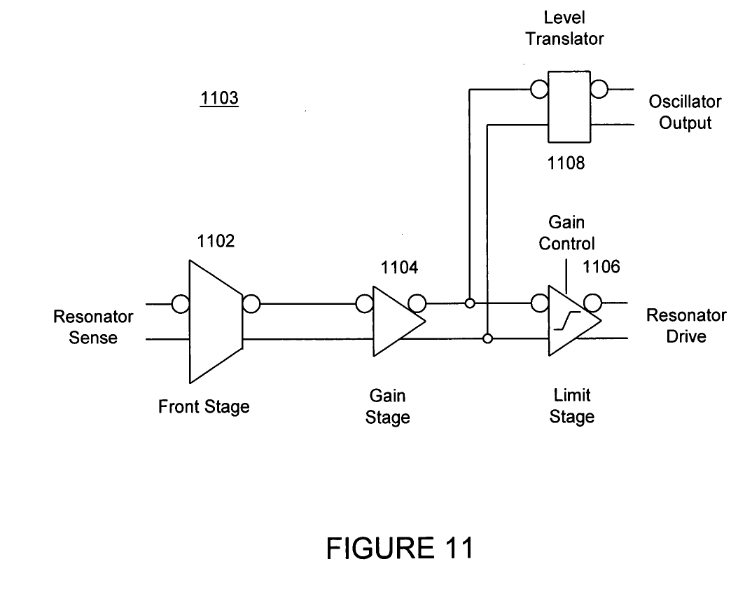

FIG. 11 is a circuit diagram of an amplifier 1103 according to an embodiment. The amplifier 1103 includes a front stage 1102, a gain stage 1104 and a limit stage 1106. The amplifier 1103 also includes a level translator 1108 that alters the level of the output signal to be appropriate for general signals in the integrated circuit technology in which the timing reference signal generating system is implemented. In one embodiment, the level translator outputs a signal with appropriate complementary metal oxide semiconductor (CMOS) levels, but embodiments are not so limited.

The embodiment described here is multistage to accommodate the relatively large gains and bandwidths required by some microelectromechanical resonators. In addition to supplying the gain and bandwidth, multistage designs allow for optimization of each stage for specialize purposes, for example gain, phase control, and clipping.

It is necessary that amplifiers used in oscillators have specific phase behavior, for instance the common single stage Pierce oscillator has approximately 90 degrees of phase lag at the input node, an additional approximate 90 degrees of phase lag at the output node, and 180 degrees phase (an inversion) internally. The multistage configuration described here allows the designer to incorporate phase at internal nodes. For example the multistage amplifier can be configured to have approximately 90 degrees of phase lag at the input node, and approximately 90 degrees of phase lag internally at the output of the first stage, and 0 or 180 degrees of phase at the internal gain or other stage. Alternatively, the multistage amplifier can be configured to have minimal phase at the input and minimal internal phase. Both are suitable depending upon the application and are intended to be included in this description.

Fine amounts of phase can be added or subtracted from the signal (i.e. phase lag or phase lead) at various nodes of the amplifier, for example the output node of the limit stage. In addition, 180 degrees of phase can be added (or subtracted) by simply swapping the two signal lines within or between any stage, or the two signal lines between the drive and the resonator or between the sense and the resonator. This fine and course phase flexibility is useful to optimize the amplifier for a specific resonator design, a specific individual resonator, or to compensate for temperature variation. These phase adjustments may be configured and driven by the control circuit 110 shown in FIG. 1.

The various amplifier stages shown in FIG. 11, including the level translator stage, are differentially coupled. However, in other embodiments, all of the amplifier stages are coupled in a single-ended manner. In yet other embodiments, some of the stages are differentially coupled, while others are coupled in a single-ended manner. The various amplifier stages shown in FIG. 11 are described in greater detail below.

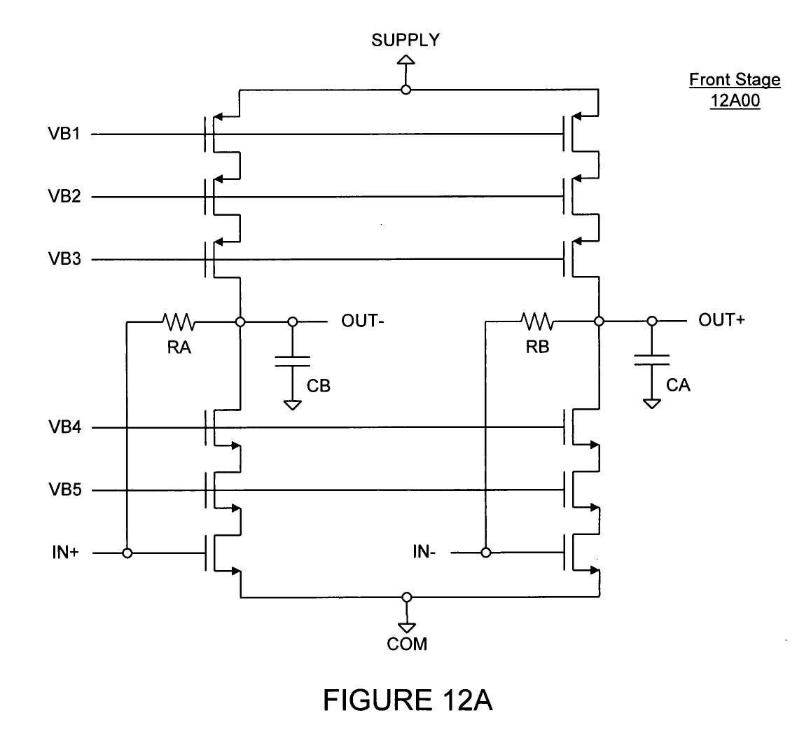

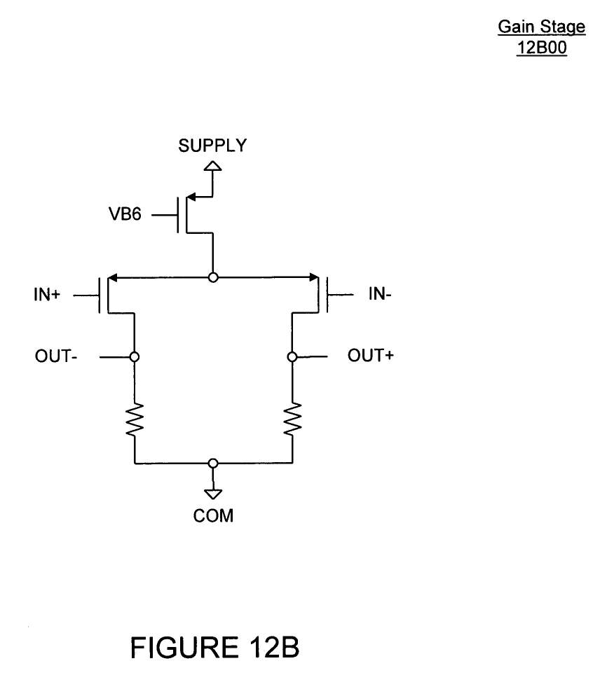

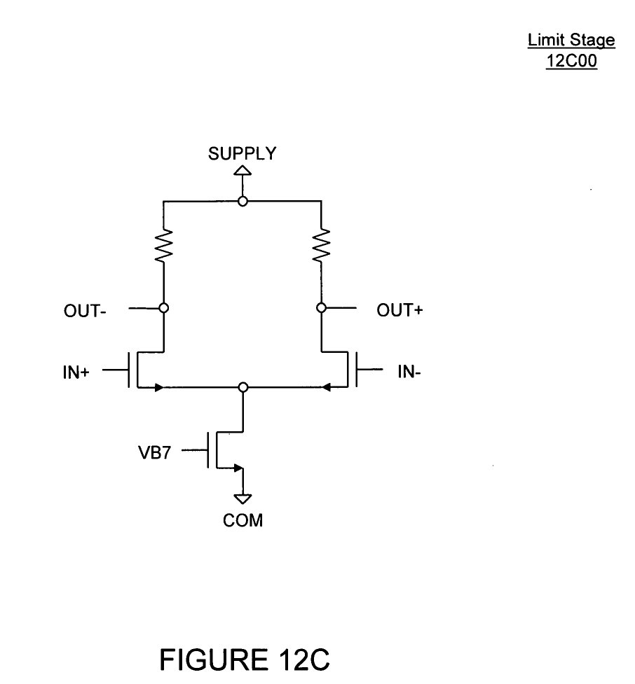

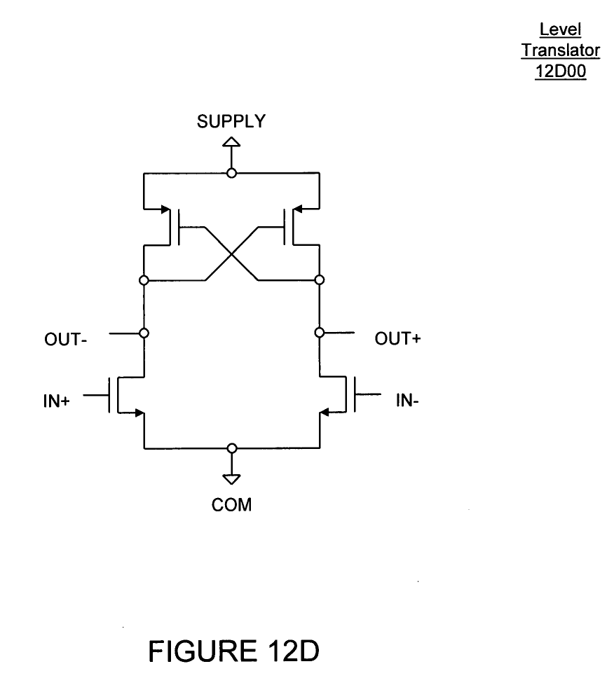

FIG. 12A is a transistor level circuit diagram of a front stage of an amplifier according to an embodiment.

The amplifier is a differential gain stage with self-biasing inputs. Depending upon the values of feedback resistors RA and RB, the output load capacitors CA and CB, and the operating frequency of the resonator, the stage can be built as a transconductance or integrating voltage gain stage.

The feedback resistors RA and RB can be sized to configure the stage as a transconductance stage or an integrating voltage gain stage. As is understood by one familiar with the art, the selection of small resistor values is made for a transconductance stage, while high values are used for voltage gain. The resistors RA and RB may be made from resistive material or layers or can be transistors built to function as resistors. When they are desired to have especially large resistances, then the transistor implementation has advantages. Other constructions, such as back-to-back diodes, are also possible.

The load capacitors, CA and CB, can be sized to set the gain and phase response. In applications where an integrator is desired then the capacitors can be made large enough to dominate at the resonator frequency. In applications where a transconductance stage is desired the capacitors can be small or non-existent.

The cascading is optionally added to increase the stage gain as is familiar to one experienced in the art. The cascade bias voltages VB1 through VB5 are generated by circuitry not shown but commonly known to one experienced in the art. The specific sizing of the transistors is a strong function of the resonator frequency, the application specifications (for example noise and power requirements), and the process in which the circuit is built. Example transistor sizes are not given here because they cannot be predetermined and procedures for deriving them are well known by those experienced in the art.

There are many ways to perform the functions described in FIG. 12A, and the description of this subset is not intended to be limiting. Any transistor level circuit that performs the described functions is intended to fall under within the scope of the embodiments disclosed and claimed herein. The circuit is given only as an example of one of many possible embodiments.

FIG. 12B is a transistor level circuit diagram of a gain stage of an amplifier according to an embodiment.

This circuit is a simple voltage gain stage. The specific sizing of the transistors and resistors is a strong function of the resonator frequency, the application specifications (for example noise and power requirements), and the process in which the circuit is built. Example transistor sizes are not given here because they cannot be predetermined and procedures for deriving them are well known by those experienced in the art.

There are many ways to build a suitable gain stage, and FIG. 12B is not intended to be limiting. Any transistor level circuit that performs a simple gain function is intended to fall within the scope of the embodiments disclosed and claimed herein. The circuit is given only as an example of one of many possible embodiments.

Furthermore, the gain stage shown in FIG. 12B is optional. In many instances the front end stage as illustrated in FIG. 12A will have sufficiently large output signal, or the limiting stage shown in FIG. 12C will have sufficiently large gain that the voltage gain stage shown in FIG. 12B is unneeded. This case is intended to fall within the scope of the embodiments disclosed and claimed herein.

FIG. 12C is a transistor level circuit diagram of a limit stage of an amplifier according to an embodiment.

The extent or clipping amplitude is a function of the values of the resistances, the bias voltage VB7, the transistor sizes, and the fabrication process. The clipping range may be set dynamically by adjusting VB7.

The specific sizing of the transistors and resistors is a strong function of the resonator frequency, the application specifications (for example noise and power requirements), and thee process in which the circuit is built. Example transistor sizes are not given here because they cannot be predetermined and procedures for deriving them are well known by those experienced in the art.

There are many ways to build a suitable gain stage, and FIG. 12C is not intended to be limiting. Any transistor level circuit that performs a simple limiting (gain and clipping) function is intended to fall within the scope of the embodiments disclosed and claimed herein. The circuit is given only as an example of one of many possible embodiments.

FIG. 12D is a transistor level circuit diagram of a level translator according to an embodiment.

The level translator is a circuit that accepts an input of one amplitude range and converts it to a different range intended to be more compatible with down-stream circuits.

This is a well known level translator design that performs the required function. There are many other ways to build a suitable translation stage, and FIG. 12D is not intended to be limiting. Any transistor level circuit that performs a simple limiting (gain and clipping) function is intended to fall under the scope of this work. The circuit is given only as an example of one of many possible embodiments.

Aspects of the methods and systems described herein may be implemented in a variety of component types, e.g., metal-oxide semiconductor field-effect transistor (“MOSFET”) technologies like complementary metal-oxide semiconductor (“CMOS”), bipolar technologies like emitter-coupled logic (“ECL”), polymer technologies (e.g., silicon-conjugated polymer and metal-conjugated polymer-metal structures), mixed analog and digital, etc.

The various components and/or functions disclosed herein may be described using any number of combinations of hardware, firmware, and/or as data and/or instructions embodied in various machine-readable or computer-readable media, in terms of their behavioral, register transfer, logic component, and/or other characteristics.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list; all of the items in the list; and any combination of the items in the list.

The above description of illustrated embodiments is not intended to be exhaustive or limited by the disclosure. While specific embodiments of, and examples for, the systems and methods are described herein for illustrative purposes, various equivalent modifications are possible, as those skilled in the relevant art will recognize. For example, the gain control function could be provided in a manner other than clipping. The resonator used in the embodiments may be any kind of resonator, although a microelectromechanical resonator is referred to herein. Although some embodiments are described with differential coupling, other embodiments may have a mix of differential coupling and single-ended coupling, for example between different amplifier stages. While certain values (e.g., for voltages) are stated in the disclosure, those particular values are illustrative examples only and are not intended to be limiting.

The teachings provided herein may be applied to other systems and methods, and not only for the systems and methods described above. The elements and acts of the various embodiments described above may be combined to provide further embodiments. These and other changes may be made to methods and systems in light of the above detailed description.

In general, in the following claims, the terms used should not be construed to be limited to the specific embodiments disclosed in the specification and the claims, but should be construed to include all systems and methods that operate under the claims. Accordingly, the method and systems are not limited by the disclosure, but instead the scope is to be determined entirely by the claims. While certain aspects are presented below in certain claim forms, the inventors contemplate the various aspects in any number of claim forms. Accordingly, the inventors reserve the right to add additional claims after filing the application to pursue such additional claim forms for other aspects as well.

1. (canceled)

2. A system for generating a timing signal, the system comprising:
a microelectromechanical (MEMS) resonator for generating an output signal and including a first node biased by a first voltage and a polarizing node biased by a polarizing voltage;
an amplifier coupled to the MEMS resonator and configured to produce a drive signal that drives the MEMS resonator; and
a first capacitor configured to capacitively couple the first node of the MEMS resonator to the amplifier, wherein the output signal generated by the MEMS resonator is controllable via the first voltage and the polarizing voltage.

3. The system of claim 2, wherein the MEMS resonator further includes a second node biased by a second voltage, and further comprising a second capacitor configured to capacitively couple the second node of the MEMS resonator to the amplifier, wherein the output signal produced by the MEMS resonator is controllable via the first voltage, the second voltage, and the polarizing voltage.

4. The system of claim 3, wherein the first voltage and the second voltage are zero voltages and the polarizing voltage is a non-zero voltage.

5. The system of claim 3, wherein the first voltage and the second voltage are non-zero voltages and the polarizing voltage is a zero voltage.

6. The system of claim 3, wherein the first voltage and the second voltage are non-zero voltages, and the polarizing voltage is a non-zero voltage that does not equal either the first voltage or the second voltage.

7. The system of claim 2, further comprising gain control circuitry coupled to the amplifier and configured to limit the drive signal that drives the MEMS resonator.

8. The system of claim 7, wherein the drive signal is a square wave signal, and the gain control circuitry is configured to clip a sine wave signal to produce the square wave signal.

9. The system of claim 8, wherein the level of clipping by the gain control circuitry is programmable.

10. The system of claim 7, wherein the gain control circuitry is configured to clamp the drive signal.

11. The system of claim 2, further comprising a first resistor coupled to the first node, wherein the first voltage is equal to the voltage across the first resistor.

12. The system of claim 11, wherein the MEMS resonator further includes a second node biased by a second voltage, and further comprising a second capacitor configured to capacitively couple the second node of the MEMS resonator to the amplifier, and a second resistor coupled to the second node, wherein the second voltage is equal to the voltage across the second resistor.

13. The system of claim 12, wherein the first resistor or the second resistor comprises a conductive material.

14. The system of claim 12, wherein the first resistor or the second resistor comprises a transistor.

15. The system of claim 12, wherein the first resistor or the second resistor comprises back-to-back diodes.

16. The system of claim 2, wherein the amplifier comprises a multistage amplifier that includes a front stage, a limit stage, and a level translator.

17. The system of claim 16, wherein the front stage, the limit stage, and the level translator are coupled differentially.

18. The system of claim 16, wherein the front stage, the limit stage, and the level translator are coupled in a single-ended fashion.

19. The system of claim 16, wherein the front stage and the limit stage are coupled differentially, and the limit stage and the level translator are coupled in a single-ended fashion.

20. The system of claim 16, wherein the front stage and the limit stage are coupled in single-ended fashion, and the limit stage and the level translator are coupled differentially.

21. The system of claim 16, wherein the multistage amplifier further includes a gain stage.

22. A system for generating a timing signal, the system comprising:
a microelectromechanical (MEMS) resonator for generating an output signal and including a first node biased by a first voltage and a polarizing node biased by a polarizing voltage;
an amplifier coupled to the MEMS resonator and configured to produce a drive signal that drives the MEMS resonator, wherein the amplifier comprises a multistage amplifier that includes at least a first stage and a second stage;
gain control circuitry coupled to the amplifier and configured to limit the drive signal that drives the MEMS resonator; and
a first capacitor configured to capacitively couple the first node of the MEMS resonator to the amplifier, wherein the output signal produced by the MEMS resonator is controllable via the first voltage and the polarizing voltage.
